(19) United States
(12) Patent Application Publication
(10) Pub. No.: US 2026/0372126 A1
(43) Pub. Date: Nov. 19, 2026

(54) FAN-OUT SEMICONDUCTOR PACKAGE

(71) Applicant: SK hynix Inc., Icheon-si Gyeonggi-do (KR)

(72) Inventors: Kyoung Tae EUN, Icheon-si Gyeonggi-do (KR); Ki Jun SUNG, Icheon-si Gyeonggi-do (KR)

(73) Assignee: SK hynix Inc., Icheon-si Gyeonggi-do (KR)

(21) Appl. No.: 19/372,483

(22) Filed: Oct. 29, 2025

(30) Foreign Application Priority Data
May 15, 2025 (KR) 10-2025-0062912

(51) Int. Cl. H10W 70/60; H10W 90/00; H10W 72/00; H10W 72/20; H10W 90/24

(52) U.S. Cl. CPC H10W 70/611; H10W 90/00; H10W 90/401; H10W 70/60; H10W 72/222; H10W 72/252; H10W 72/877; H10W 72/884; H10W 90/24; H10W 90/724; H10W 90/732; H10W 90/754

(57) ABSTRACT

A fan-out semiconductor package includes a first mold layer; a first semiconductor chip disposed on the first mold layer; a first metal contact disposed on the first semiconductor chip; a second mold layer covering the first semiconductor chip and surrounding the first metal contact; and a bonding pad disposed on the first metal contact. The fan-out semiconductor package also includes a bridge die mounted on the bonding pad; a second semiconductor chip disposed on the second mold layer; a second metal contact disposed on the second semiconductor chip; a third mold layer covering the second semiconductor chip and surrounding the second metal contact and the bridge die; and a redistribution layer disposed on the second metal contact, the bridge die, and the third mold layer.

### CROSS-REFERENCE TO RELATED APPLICATION

The present application claims priority under 35 U.S.C. §119(a) to Korean patent application number 10-2025-0062912 filed in the Korean Intellectual Property Office on May 15, 2025, which application is incorporated herein by reference in its entirety.

### TECHNICAL FIELD

Embodiments of the present disclosure relate to a fan-out semiconductor package.

### BACKGROUND

A semiconductor chip includes an integrated circuit for storing data or processing data. In addition, a semiconductor chip has a chip pad for inputting data into an integrated circuit or outputting data from an integrated circuit. A semiconductor package electrically connects a semiconductor chip to an external device.

Various methods can be applied to electrically connect a chip pad to an external device. A semiconductor package using a redistribution layer has a redistribution pattern electrically connected to the chip pad. Among semiconductor packages using a redistribution layer, a fan-out package is a technology that extends a redistribution pattern connected to a chip pad outside an area where a semiconductor chip is disposed and places an external connection terminal on the extended redistribution pattern. The number and pitch of external connection terminals in a fan-out package are not limited by the size of the semiconductor chip, thereby implementing high-density input/output (I/O).

### SUMMARY

According to an embodiment of the present disclosure, a fan-out semiconductor package includes: a first mold layer; a first semiconductor chip disposed on the first mold layer; a first metal contact disposed on the first semiconductor chip; a second mold layer covering the first semiconductor chip and surrounding the first metal contact; a bonding pad disposed on the first metal contact; a bridge die mounted on the bonding pad; a second semiconductor chip disposed on the second mold layer; a second metal contact disposed on the second semiconductor chip; a third mold layer covering the second semiconductor chip and surrounding the second metal contact and the bridge die; and a redistribution layer disposed on the second metal contact, the bridge die, and the third mold layer.

According to an embodiment of the present disclosure, a fan-out semiconductor package includes: a first mold layer; a first semiconductor chip disposed on the first mold layer; a first metal contact disposed on the first semiconductor chip; a second mold layer covering the first semiconductor chip and surrounding the first metal contact; a first bonding pad disposed on the first metal contact; a first bridge die mounted on the first bonding pad; a second semiconductor chip disposed on the second mold layer; a second metal contact disposed on the second semiconductor chip; a third mold layer covering the second semiconductor chip and surrounding the second metal contact and the first bridge die; a second bonding pad disposed on the first bridge die; a third bonding pad disposed on the second metal contact; a second bridge die mounted on the second bonding pad; a third bridge die mounted on the third bonding pad; a third semiconductor chip mounted on the third mold layer; a third metal contact disposed on the third semiconductor chip; a fourth mold layer covering the third semiconductor chip and surrounding the third metal contact, the second bridge die and the third bridge die; and a redistribution layer disposed on the third metal contact, the second bridge die, the third bridge die, and the fourth mold layer.

### BRIEF DESCRIPTION OF THE DRAWINGS

The present disclosure will be more fully understood from the detailed description and accompanying drawings provided below, which are provided for illustration only and are not intended to limit the present disclosure.

FIG. 1 is a cross-sectional view of a fan-out semiconductor package according to an embodiment of the present disclosure.

FIG. 2 is an enlarged view of section A of FIG. 1.

FIG. 3 to FIG. 8 are cross-sectional views for explaining a method for manufacturing a fan-out semiconductor package according to an embodiment of the present disclosure.

FIGS. 9, 11, and 13 are cross-sectional views of fan-out semiconductor packages according to embodiments of the present disclosure.

FIG. 10 is an enlarged view of section B of FIG. 9.

FIG. 12 is an enlarged view of section C of FIG. 11.

### DETAIL DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “under,” or “next to” another element, the elements may directly contact each other or an intervening element may be disposed between the elements.

Terms such as “vertical,” “horizontal,” “top,” “bottom,” “below,” “under,” “on,” “side,” “upper,” “lower,” “left,” “column,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

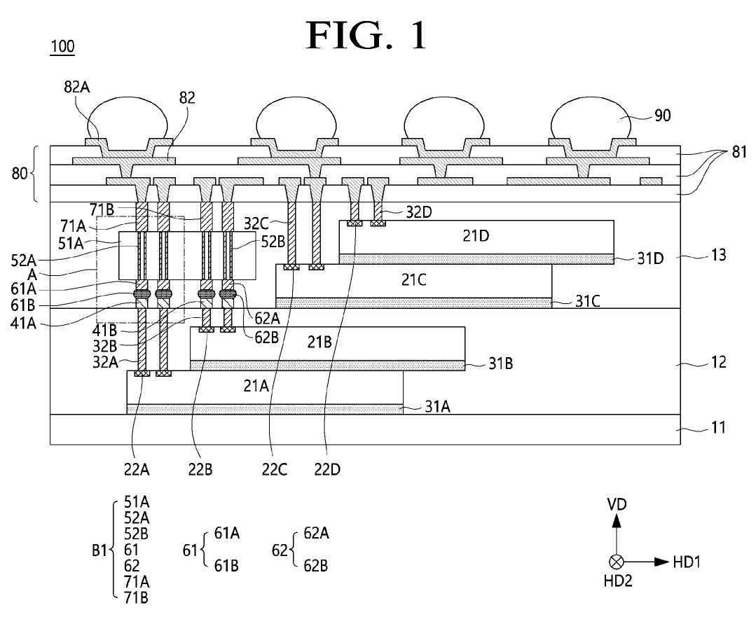

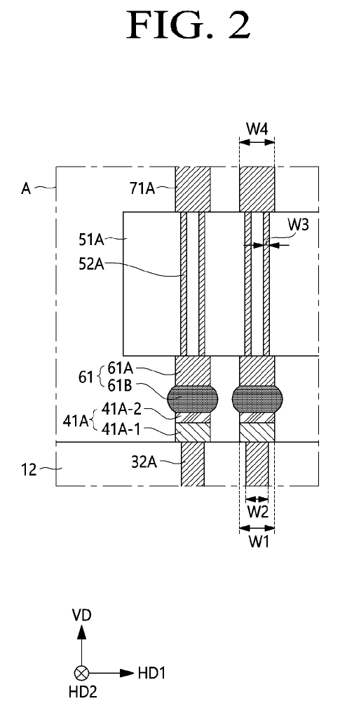

FIG. 1 is a cross-sectional view of a fan-out semiconductor package according to an embodiment of the present disclosure, and FIG. 2 is an enlarged view of section A of FIG. 1. For the purposes of description, a coordinate system is shown for each figure of the drawings having a first horizontal direction HD1 pointing to the right, a second horizontal direction HD2 pointing into the page, and a vertical direction VD pointing upward.

Referring to FIG. 1, a fan-out semiconductor package 100 according to one embodiment of the present disclosure includes a first mold layer 11, a second mold layer 12, and a third mold layer 13, a first semiconductor chip 21A, a second semiconductor chip 21B, a third semiconductor chip 21C, and a fourth semiconductor chip 21D, a first bridge die B1, and a redistribution layer 80.

The first mold layer 11 includes an insulating layer. The insulating layer may include an epoxy molding compound (EMC). The epoxy molding compound may include a resin and a filler. The first mold layer 11 may include an epoxy molding compound film that is processed into a film form of an epoxy molding compound.

The first semiconductor chip 21A and the second semiconductor chip 21B are stacked on the first mold layer 11. The first semiconductor chip 21A is disposed on the first mold layer 11, and the second semiconductor chip 21B is disposed on the first semiconductor chip 21A. In FIG. 1, two semiconductor chips are stacked on the first mold layer 11, but other embodiments are not limited thereto. One semiconductor chip may be disposed on the first mold layer 11, or three or more semiconductor chips may be stacked.

The first semiconductor chip 21A includes a first integrated circuit. The first integrated circuit may be implemented in various ways depending on the type of the first semiconductor chip 21A. In one embodiment, the first semiconductor chip 21A may be a memory die, and the first integrated circuit may include at least one memory cell. The memory may include volatile memory or nonvolatile memory. The volatile memory may include a dynamic random-access memory (DRAM) and a static random-access memory (SRAM). The nonvolatile memory may include NAND, NOR, phase change random-access memory (PRAM), and magneto-resistive random-access memory (MRAM).

The first semiconductor chip 21A has a first chip pad 22A on an upper surface. The first chip pad 22A is connected to the first integrated circuit. The first chip pad 22A is arranged on one of the first horizontal direction HD1 edges of the upper surface of the first semiconductor chip 21A, for example, on the left edge. Although only two first chip pads 22A are visible in FIG. 1, a plurality of first chip pads are arranged in two columns along the second horizontal direction HD2. Although not shown, in other embodiments, the first chip pads may be arranged in one column or in three or more columns.

A first metal contact 32A is disposed on the first chip pad 22A. The first metal contact 32A may be a plating metal layer. The plating metal layer may include copper (Cu). The first metal contact 32A may be a copper pillar.

A first adhesive layer 31A is attached to a lower surface of a first semiconductor chip 21A, and the first semiconductor chip 21A is attached to the first mold layer 11 by the first adhesive layer 31A.

The second semiconductor chip 21B is offset in the first horizontal direction HD1 with respect to the first semiconductor chip 21A so that the first metal contact 32A is exposed. The second semiconductor chip 21B is disposed next to the first metal contact 32A and partially overlaps with the first semiconductor chip 21A. The first metal contact 32A extends in the vertical direction VD while passing along the side of the second semiconductor chip 21B.

The second semiconductor chip 21B includes a second integrated circuit (not shown). The second integrated circuit may be implemented in various ways depending on the type of the second semiconductor chip 21B. In one embodiment, the second semiconductor chip 21B may be a memory die, and the second integrated circuit may include at least one memory cell.

The second semiconductor chip 21B has a second chip pad 22B on an upper surface. The second chip pad 22B is connected to the second integrated circuit. The second chip pad 22B is arranged on one of the first horizontal direction HD1 edges of the upper surface of the second semiconductor chip 21A, for example, on the left edge. Although only two second chip pads 22B are visible in FIG. 1, a plurality of second chip pads are arranged in two columns along the second horizontal direction HD2. Although not shown, the second chip pads may be arranged in one column or in three or more columns.

A second metal contact 32B is disposed on the second chip pad 22B. The second metal contact 32B may be a plating metal layer. The plating metal layer may include copper. The second metal contact 32B may be a copper pillar.

A second adhesive layer 31B is attached to a lower surface of the second semiconductor chip 21B, and the second semiconductor chip 21B is attached to the first semiconductor chip 21A by the second adhesive layer 31B.

The second mold layer 12 covers the first semiconductor chip 21A and the second semiconductor chip 21B and surrounds the first metal contact 32A and the second metal contact 32B. The second mold layer 12 seals the first semiconductor chip 21A and the second semiconductor chip 21B and the first metal contact 32A and the second metal contact 32B. The second mold layer 12 includes an insulating layer. The insulating layer may include an epoxy molding compound.

Upper ends of the first metal contact 32A and the second metal contact 32B are exposed at an upper surface of the second mold layer 12. The upper ends of the first metal contact 32A and the second metal contact 32B are arranged on the same plane as the upper surface of the second mold layer 12.

A first bonding pad 41A is arranged on the first metal contact 32A. The width of the first bonding pad 41A in the first horizontal direction HD1 is greater than the width of the first metal contact 32A in the first horizontal direction HD1. As illustrated in FIG. 2, the width of the first bonding pad 41A in the first horizontal direction HD1 is W1, and the width of the first metal contact 32A in the first horizontal direction HD1 is W2. W1 is greater than W2. The first bonding pad 41A is arranged on the upper surface of the first metal contact 32A and the upper surface of the second mold layer 12 around the first metal contact 32A. The first bonding pad 41A may have a planar area greater than the planar area of the first metal contact 32A.

As illustrated in FIG. 2, the first bonding pad 41A includes a barrier metal layer 41A-1 and a bonding metal layer 41A-2. The barrier metal layer 41A-1 is disposed on the first metal contact 32A. The barrier metal layer 41A-1 covers an upper surface of the first metal contact 32A. The bonding metal layer 41A-2 is disposed on the barrier metal layer 41A-1. The bonding metal layer 41A-2 covers an upper surface of the barrier metal layer 41A-1. The barrier metal layer 41A-1 may include nickel (Ni). The barrier metal layer 41A-1 may be a nickel layer. The bonding metal layer 41A-2 may include gold (Au). The bonding metal layer 41A-2 may be a gold layer.

A second bonding pad 41B is arranged on the second metal contact 32B. The width of the second bonding pad 41B in the first horizontal direction HD1 is greater than the width of the second metal contact 32B in the first horizontal direction HD1. The second bonding pad 41B is arranged on the upper surface of the second metal contact 32B and the upper surface of the second mold layer 12 around the second metal contact 32B. The second bonding pad 41B may have a greater planar area than the planar area of the second metal contact 32B. The second bonding pad 41B may be composed of the same material as the first bonding pad 41A.

A first bridge die B1 is mounted on the first bonding pad 41A and the second bonding pad 41B. The first bridge die B1 includes a first body layer 51A, a first bottom bump 61 and a second bottom bumps 62, a first top bump 71A and a second top bump 71B, and a first through-electrode 52A and a second through-electrode 52B.

The first body layer 51A may include silicon. The first bottom bump 61 and the second bottom bump 62 are arranged under the first body layer 51A. The first bottom bump 61 includes a first metal layer 61A under the first body layer 51A and a first solder layer 61B under the first metal layer 61A. The solder layer 61B is bonded on the first bonding pad 41A. The second bottom bump 62 has a structure similar to the first bottom bump 61. The second bottom bump 62 includes a second metal layer 62A under the first body layer 51A and a second solder layer 62B under the second metal layer 62A.

The first top bump 71A and the second top bump 71B are arranged on the first body layer 51A. The first top bump 71A overlaps with the first bottom bump 61 in the vertical direction VD. The second top bump 71B overlaps with the second bottom bump 62 in the vertical direction VD. The first top bump 71A and the second top bump 71B include a metal. The metal may include copper. The first top bump 71A and the second top bump 71B may be copper bumps.

The first through-electrode 52A extends through or penetrates the first body layer 51A in the vertical direction VD. A lower end of the first through-electrode 52A is connected to the first bottom bump 61, and an upper end of the first through-electrode 52A is connected to the first top bump 71A. The first through-electrode 52A electrically connects the first bottom bump 61 and the first top bump 71A. The width of the first through-electrode 52A in the first horizontal direction HD1 is less than the width of the first bottom bump 61 in the first horizontal direction HD1 and the width of the first top bump 71A in the first horizontal direction HD1. As illustrated in FIG. 2, the width of the first through-electrode 52A in the first horizontal direction HD1 is W3, and the width of the first top bump 71A in the first horizontal direction HD1 is W4. W3 is less than W4. Two first through-electrodes 52A are arranged between the first bottom bump 61 and the first top bump 71A to electrically connect the first bottom bump 61 and the first top bump 71A. Although the number of first through-electrodes 52A connecting the first bottom bump 61 and the first top bump 71A is two in FIGS. 1 and 2, other embodiments are not limited thereto. Although not illustrated, the number of first through-electrodes connecting the first bottom bump and the first top bump may be one or three or more.

The second through-electrode 52B extends through or penetrates the first body layer 51A in the vertical direction VD. A lower end of the second through-electrode 52B is connected to the second bottom bump 62, and an upper end of the second through-electrode 52B is connected to the second top bump 71B. The second through-electrode 52B electrically connects the second bottom bump 62 and the second top bump 71B. The width of the second through-electrode 52B in the first horizontal direction HD1 is less than the width of the second bottom bump 62 in the first horizontal direction HD1 and the width of the second top bump 71B in the first horizontal direction HD1. Two second through-electrodes 52B are arranged between the second bottom bump 62 and the second top bump 71B to electrically connect the second bottom bump 62 and the second top bump 71B. In FIG. 1, the number of second through-electrodes 52B connecting the second bottom bump 62 and the second top bump 71B is two, but other embodiments are not limited thereto. Although not shown, the number of second through-electrodes connecting the second bottom bump and the second top bump may be one or three or more. The first through-electrode 52A and the second through-electrode 52B include metal. The metal may include copper. The first through-electrode 52A and the second through-electrode 52B may be copper electrodes.

A third semiconductor chip 21C and a fourth semiconductor chip 21D are stacked on the second mold layer 12. The third semiconductor chip 21C is disposed on the second mold layer 12, and the fourth semiconductor chip 21D is disposed on the third semiconductor chip 21C. In FIG. 1, two semiconductor chips are stacked on the second mold layer 12, but other embodiments are not limited thereto. One semiconductor chip may be disposed on the second mold layer 12, or three or more semiconductor chips may be stacked.

The third semiconductor chip 21C includes a third integrated circuit. The third integrated circuit may be implemented in various ways depending on the type of the third semiconductor chip 21C. In one embodiment, the third semiconductor chip 21C may be a memory die, and the third integrated circuit may include at least one memory cell.

The third semiconductor chip 21C has a third chip pad 22C on an upper surface. The third chip pad 22C is connected to the third integrated circuit. The third chip pad 22C is arranged on one of the first horizontal direction HD1 edges of an upper surface of the third semiconductor chip 21C, for example, on the left edge. Although only two third chip pads 22C are visible in FIG. 1, a plurality of third chip pads are arranged in two columns along the second horizontal direction HD2. In other embodiments, the third chip pads may be arranged in one column or in three or more columns.

A third metal contact 32C is arranged on the third chip pad 22C. The third metal contact 32C may be a plating metal layer. The plating metal layer may include copper. The third metal contact 32C may be a copper pillar.

A third adhesive layer 31C is attached to a lower surface of the third semiconductor chip 21C, and the third semiconductor chip 21C is attached to the second mold layer 12 by the third adhesive layer 31C.

The fourth semiconductor chip 21D is offset relative to the third semiconductor chip 21C so that the third metal contact 32C is exposed. The direction in which the fourth semiconductor chip 21D is offset relative to the third semiconductor chip 21C is the same as the direction in which the second semiconductor chip 21B is offset relative to the first semiconductor chip 21A. The fourth semiconductor chip 21D is disposed next to the third metal contact 32C and partially overlaps with the third semiconductor chip 21C. The third metal contact 32C extends substantially in the vertical direction VD while passing a side of the fourth semiconductor chip 21D.

The fourth semiconductor chip 21D includes a fourth integrated circuit (not shown). The fourth integrated circuit may be implemented in various ways depending on the type of the fourth semiconductor chip 21D. In one embodiment, the fourth semiconductor chip 21D may be a memory die, and the fourth integrated circuit may include at least one memory cell.

The fourth semiconductor chip 21D has a fourth chip pad 22D on an upper surface. The fourth chip pad 22D is connected to the fourth integrated circuit. The fourth chip pad 22D is arranged on one of the first horizontal direction HD1 edges of the upper surface of the fourth semiconductor chip 21A, for example, on the left edge. Although only two fourth chip pads 22D are visible in FIG. 1, a plurality of fourth chip pads are arranged in two columns along the second horizontal direction HD2. Although not shown, the fourth chip pads may be arranged in one column or in three or more columns.

A fourth metal contact 32D is arranged on the fourth chip pad 22D. The fourth metal contact 32D may be a plating metal layer. The plating metal layer may include copper. The fourth metal contact 32D may be a copper pillar.

Although not shown, a base metal layer may be further disposed between the first chip pad 22A and the first metal contact 32A, between the second chip pad 22B and the second metal contact 32B, between the third chip pad 22C and the third metal contact 32C, and between the fourth chip pad 22D and the fourth metal contact 32D. The base metal layer electrically connects between the first chip pad 22A and the first metal contact 32A, between the second chip pad 22B and the second metal contact 32B, between the third chip pad 22C and the third metal contact 32C, and between the fourth chip pad 22D and the fourth metal contact 32D. The base metal layer limits or suppresses the metal included in the first metal contact 32A, the second metal contact 32B, the third metal contact 32C, and the fourth metal contact 32D from diffusing into the first semiconductor chip 21A, the second semiconductor chip 21B, the third semiconductor chip 21C, and the fourth semiconductor chip 21D. The base metal layer may include nickel. The base metal layer may be a nickel layer.

A fourth adhesive layer 31D is attached to a lower surface of the fourth semiconductor chip 21D, and the fourth semiconductor chip 21D is attached to the third semiconductor chip 21C by the fourth adhesive layer 31D.

The third mold layer 13 covers the third semiconductor chip 21C and the fourth semiconductor chip 21D and surrounds the first bridge die B1, the third metal contact 32C and the fourth metal contact 32D. The third mold layer 13 seals the third semiconductor chip 21C and the fourth semiconductor chip 21D, the first bridge die B1, and the third metal contact 32C and the fourth metal contact 32D. The upper ends of the third metal contact 32C and the fourth metal contact 32D and the upper ends of the first top bump 71A and the second top bump 71B of the first bridge die B1 are exposed at an upper surface of the third mold layer 13. The upper ends of the third metal contact 32C and the fourth metal contact 32D and the upper ends of the first top bump 71A and the second top bump 71B are disposed on the same plane as the upper surface of the third mold layer 13.

The redistribution layer 80 is disposed on the third metal contact 32C and the fourth metal contact 32D, the first bridge die B1, and the third mold layer 13. The redistribution layer 80 includes a dielectric layer 81 and redistribution patterns 82. The redistribution pattern 82 is connected to at least one of the third metal contact 32C and the fourth metal contact 32D, and the first top bump 71A and the second top bump 71B.

The first semiconductor chip 21A is connected to the redistribution pattern 82 through the first metal contact 32A, the first bonding pad 41A, and the first bridge die B1. The second semiconductor chip 21B is connected to the redistribution pattern 82 through the second metal contact 32B, the second bonding pad 41B, and the first bridge die B1. The third semiconductor chip 21C is connected to the redistribution pattern 82 through the third metal contact 32C. The fourth semiconductor chip 21D is connected to the redistribution pattern 82 through the fourth metal contact 32D.

The redistribution patterns 82 are insulated from each other by the dielectric layer 81. Some of the redistribution patterns 82 include an under-bump metallurgy (UBM) 82A. An external connection terminal 90 is connected on the UBM 82A. The external connection terminal 90 includes a solder ball.

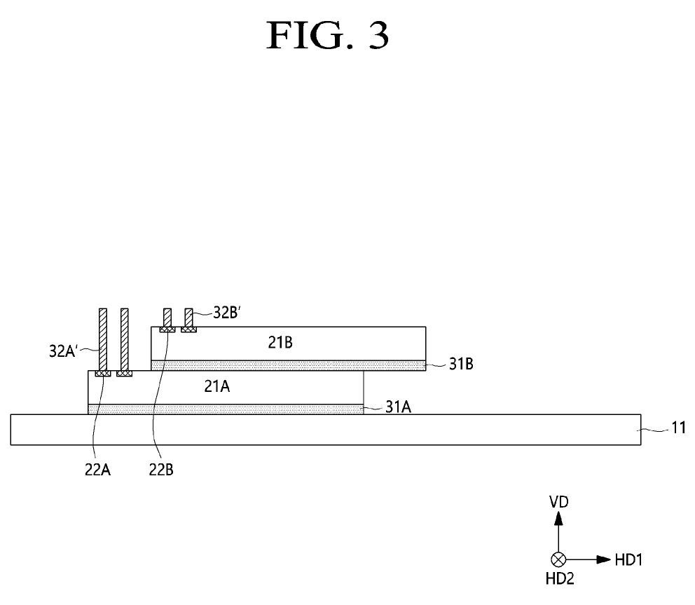

FIGS. 3-8 are cross-sectional views for explaining a method for manufacturing a fan-out semiconductor package according to an embodiment of the present disclosure.

Referring to FIG. 3, a first semiconductor chip 21A having a first preliminary metal contact 32A’ is disposed on a first mold layer 11. The first semiconductor chip 21A is attached to the first mold layer 11 by a first adhesive layer 31A.

The process of forming the first preliminary metal contact 32A’ may include forming a seed metal layer on the first semiconductor chip 21A, forming a plating resist pattern having an opening that provides a mold shape for the first preliminary metal contact 32A’ on the seed metal layer, forming a metal pillar in the opening of the plating resist pattern, removing the plating resist pattern, and removing the seed metal layer that does not overlap with the metal pillar. The first preliminary metal contact 32A’ includes a seed metal layer and a metal pillar.

The seed metal layer may be formed by a deposition method such as sputtering. The metal pillar may be grown by an electroplating process. The seed metal layer and the metal pillar include copper.

Although not shown, before forming the seed metal layer, a base metal layer may be formed on the first semiconductor chip 21A, the seed metal layer that does not overlap with the metal pillar may be removed, and the base metal layer exposed by the removal of the seed metal layer may be removed. The base metal layer may be formed by a deposition method such as sputtering. The base metal layer may include nickel. The base metal layer may be a nickel layer.

A second semiconductor chip 21B on which a second preliminary metal contact 32B’ is formed is stacked on the first semiconductor chip 21A. The second semiconductor chip 21B is offset in the first horizontal direction HD1 with respect to the first semiconductor chip 21A so that the first preliminary metal contact 32A’ is exposed. The second semiconductor chip 21B is attached to the first semiconductor chip 21A by a second adhesive layer 31B. The second preliminary metal contact 32B’ may be formed in the same process or the dame method as the first preliminary metal contact 32A’.

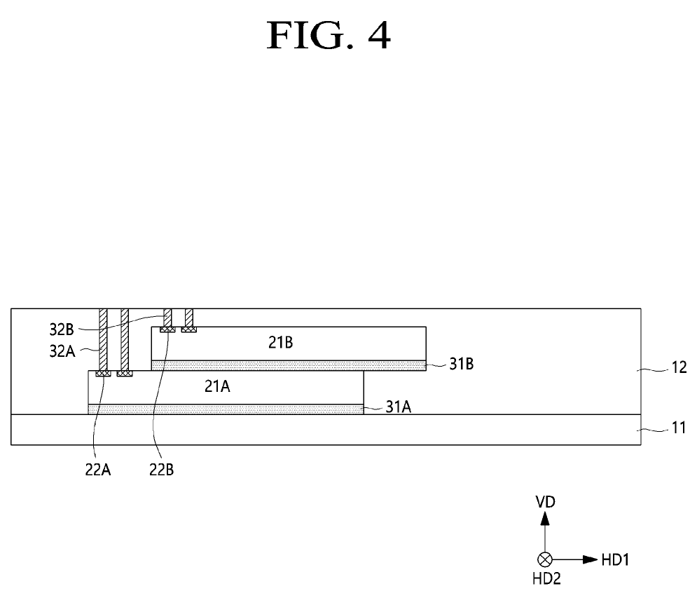

Referring to FIG. 4, a second mold layer 12 is formed.

Forming the second mold layer 12 includes forming a first preliminary mold layer covering the first semiconductor chip 21A, the second semiconductor chip 21B, the first preliminary metal contacts 32A’ and the second preliminary metal contacts 32B’ through a molding process and thinning the first preliminary mold layer.

The molding process may include mounting a first mold layer 11 in which the first semiconductor chip 21A, the second semiconductor chip 21B, the first preliminary metal contacts 32A’, and the second preliminary metal contacts 32B’ are arranged in a mold (not shown), introducing a liquid sealant into the mold, and curing the introduced sealant. The sealant may include an epoxy molding compound.

The thinning process may include a chemical mechanical polishing (CMP) process or a grinding process. In the thinning process, the first preliminary metal contacts 32A’ and the second preliminary metal contacts 32B’ are polished together with the first preliminary mold layer to form the first metal contact 32A and the second metal contact 32B. By the thinning process, the upper ends of the first metal contact 32A and the second metal contact 32B are exposed at an upper surface of the second mold layer 12. The upper ends of the first metal contact 32A and the second metal contact 32B may be arranged on substantially the same plane as the upper surface of the second mold layer 12.

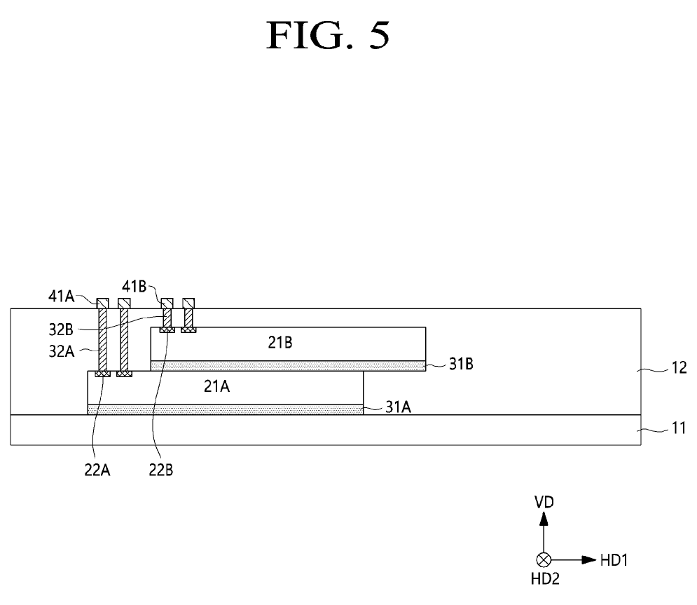

Referring to FIG. 5, the first bonding pad 41A and the second bonding pad 41B are formed on the first metal contact 32A and the second metal contact 32B, respectively.

Each of the first bonding pad 41A and the second bonding pad 41B may include a barrier metal layer and a bonding metal layer disposed on the barrier metal layer. The barrier metal layer may include nickel. The barrier metal layer may be a nickel layer. The bonding metal layer may include gold. The bonding metal layer may be a gold layer.

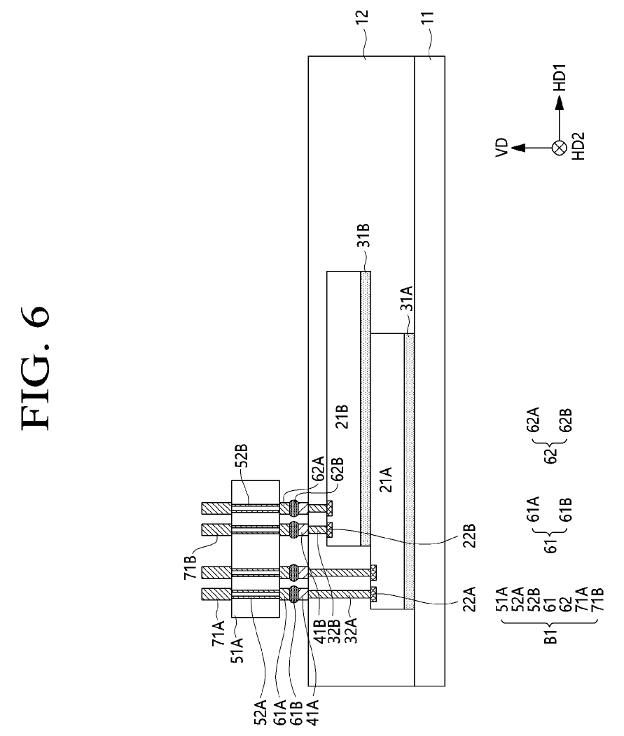

Referring to FIG. 6, a first bridge die B1 is mounted on the first bonding pad 41A and the second bonding pad 41B.

The first bridge die B1 includes a first body layer 51A, a first bottom bump 61, a second bottom bump 62, a first top bump 71A, a second top bump 71B, a first through-electrode 52A, and a second through-electrode 52B.

The process of forming the first bridge die B1 includes forming the first through-electrode 52A and the second through-electrode 52B that extend through or penetrate the first body layer 51A in the vertical direction VD, forming first bottom bump 61 and the second bottom bump 62 on the lower surface of the first bridge die B1, and forming the first top bump 71A and the second top bump 71B on the upper surface of the first bridge die B1.

The first bottom bump 61 includes a first metal layer 61A under the lower surface of the first body layer 51A and a first solder layer 61B under the first metal layer 61A. The second bottom bump 62 includes a second metal layer 62A under the lower surface of the first body layer 51A and a second solder layer 62B under the second metal layer 62A. The first solder layer 61B of the first bottom bump 61 is bonded on the first bonding pad 41A, and the second solder layer 62B of the second bottom bump 62 is bonded on the second bonding pad 41B.

The process of forming the first bottom bump 61 and the second bottom bump 62 may include forming a seed metal layer on the lower surface of the first body layer 51A, forming a plating resist pattern having openings that provide a mold shape for the first bottom bump 61 and the second bottom bump 62 on the seed metal layer, forming a plating metal layer in the openings of the plating resist pattern, forming a solder layer on the plating metal layer, removing the plating resist pattern, removing the seed metal layer that does not overlap with the solder layer, and reflowing the solder layer. The seed metal layer and the plating metal layer may include copper.

The process of forming the first top bump 71A and the second top bump 71B may include forming a seed metal layer on the upper surface of the first body layer 51A, forming a plating resist pattern having openings that provide a mold shape for the first top bump 71A and the second top bump 71B on the seed metal layer, forming a plating metal layer in the openings of the plating resist pattern, removing the plating resist pattern, and removing the seed metal layer that does not overlap with the plating metal layer. The seed metal layer and the plating metal layer may include copper.

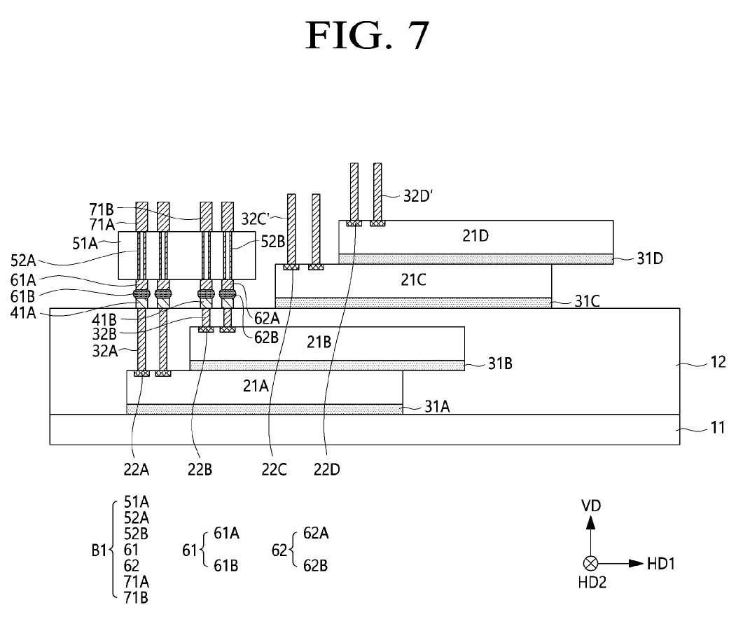

Referring to FIG. 7, a third semiconductor chip 21C having a third preliminary metal contact 32C’ may be disposed on a second mold layer 12. The third semiconductor chip 21C is attached to the second mold layer 12 by a third adhesive layer 31C.

A fourth semiconductor chip 21D having a fourth preliminary metal contact 32D’ may be stacked on a third semiconductor chip 21C. The fourth semiconductor chip 21D is offset in a first horizontal direction HD1 with respect to the third semiconductor chip 21C so that the third preliminary metal contact 32C’ is exposed. The direction in which the fourth semiconductor chip 21D is offset with respect to the third semiconductor chip 21C is the same as the direction in which the second semiconductor chip 21B is offset with respect to the first semiconductor chip 21A. The fourth semiconductor chip 21D is attached to the third semiconductor chip 21C by a fourth adhesive layer 31D.

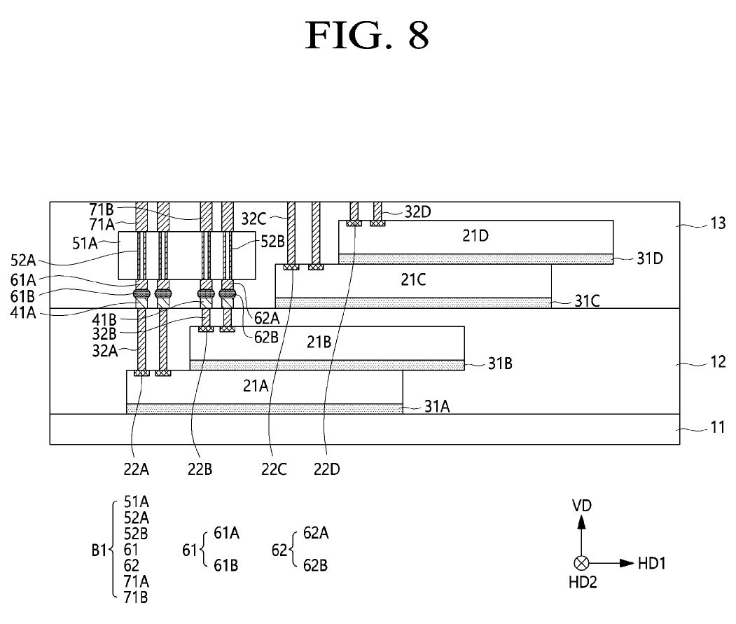

Referring to FIG. 8, a third mold layer 13 is formed.

Forming the third mold layer 13 includes forming a second preliminary mold layer covering the first bridge die B1, the third semiconductor chip 21C, the fourth semiconductor chip 21D, the third preliminary metal contact 32C’, and the fourth preliminary metal contact 32D’ through a molding process and thinning out the second preliminary mold layer.

In the thinning process, the third preliminary metal contact 32C’ and the fourth preliminary metal contact 32D’ are polished together with the second preliminary mold layer to form the third metal contact 32C and the fourth metal contact 32D. By the thinning process, the upper ends of the first top bump 71A and the second top bump 71B of the first bridge die B1 and the upper ends of the third metal contact 32C and the fourth metal contact 32D are exposed at an upper surface of the third mold layer 13. The upper ends of the first top bump 71A and the second top bump 71B and the upper ends of the third metal contact 32C and the fourth metal contact 32D are arranged on the same plane as the upper surface of the third mold layer 13.

Referring back to FIG. 1, a redistribution layer 80 is formed, and a connection terminal 90 is arranged on the UBM 82A of the redistribution layer 80.

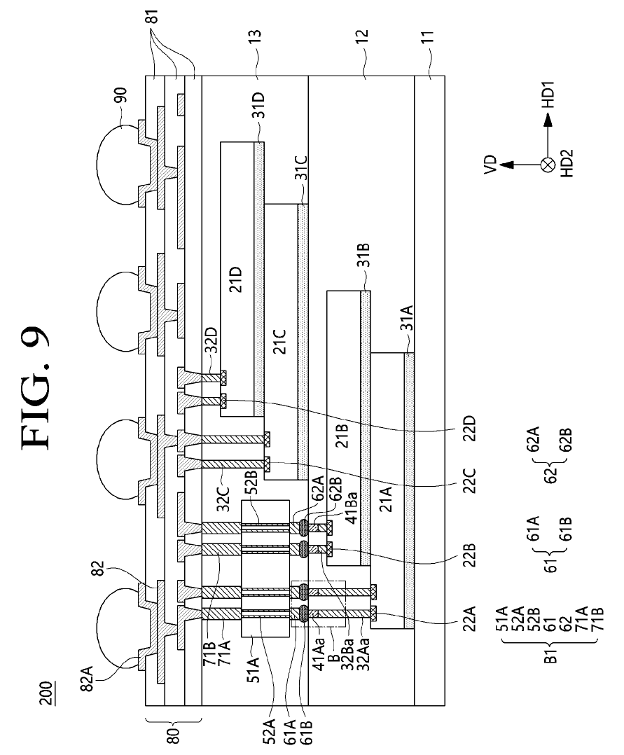

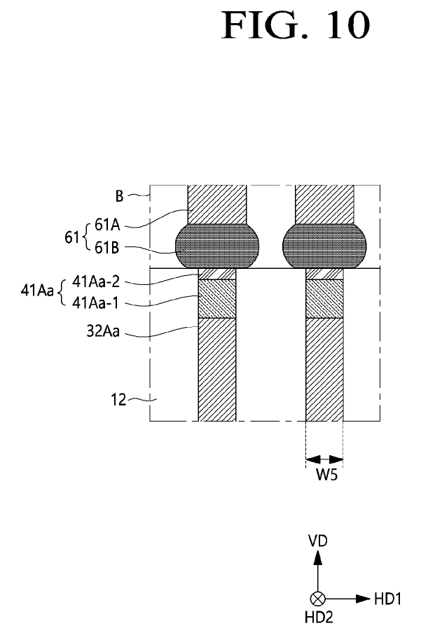

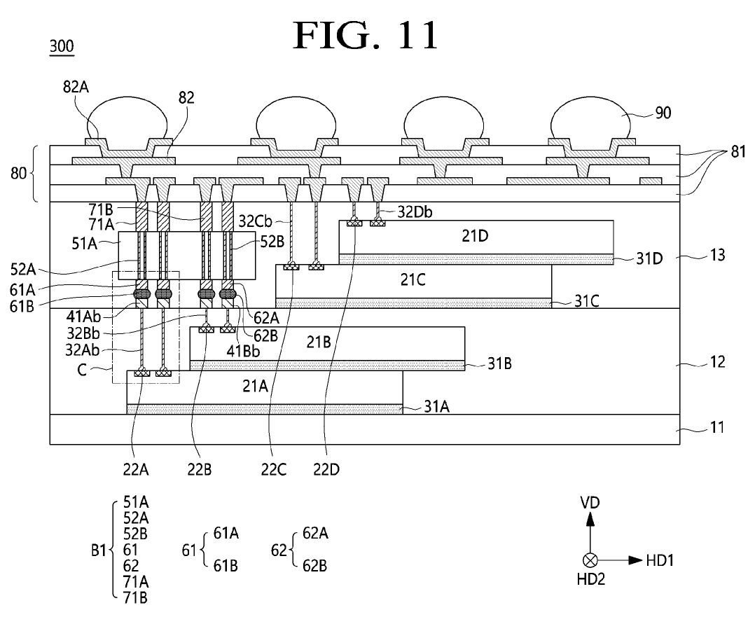

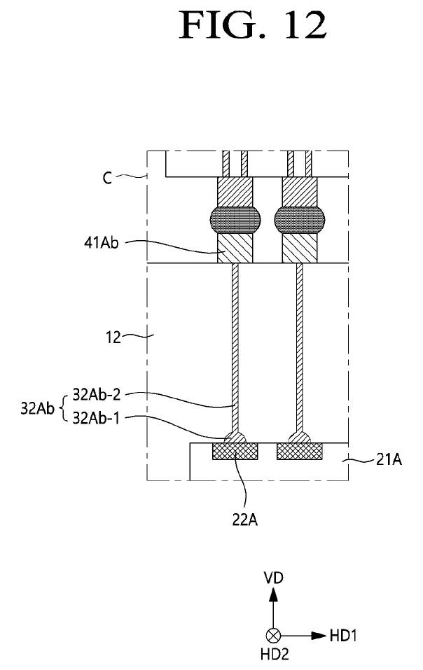

FIGS. 9, 11, and 13 are cross-sectional views of fan-out semiconductor packages according to embodiments of the present disclosure, and FIG. 10 is an enlarged view of section B of FIGS. 9, and 12 is an enlarged view of section C of FIG. 11. For simplicity, duplicate descriptions of the same configurations as those described with reference to FIGS. 1-8 are omitted.

Referring to FIGS. 9 and 10, the upper ends of a first metal contact 32Aa and a second metal contact 32Ba of the fan-out semiconductor package 200 according to an embodiment of the present disclosure are arranged below an upper surface of the second mold layer 12. The upper end of the first metal contact 32Aa is disposed closer to the upper surface of the first semiconductor chip 21A than the upper surface of the second mold layer 12. The upper end of the second metal contact 32Ba is disposed closer to the upper surface of the second semiconductor chip 21B than the upper surface of the second mold layer 12.

A first bonding pad 41Aa is disposed on the first metal contact 32Aa. The first bonding pad 41Aa covers the upper surface of the first metal contact 32Aa. The width of the first bonding pad 41Aa in the first direction HD1 is the same as the width of the first metal contact 32Aa in the first direction HD1. As shown in FIG. 10, the width of the first bonding pad 41Aa in the first direction HD1 and the width of the first metal contact 32Aa in the first direction HD1 are W5. The upper surface of the first bonding pad 41Aa is disposed on the same plane as the upper surface of the second mold layer 12. The second mold layer 12 surrounds the side surface of the first bonding pad 41Aa.

A second bonding pad 41Ba is disposed on the second metal contact 32Ba. The second bonding pad 41Ba covers the upper surface of the second metal contact 32Ba. The width of the second bonding pad 41Ba in the first direction HD1 is the same as the width of the second metal contact 32Ba in the first direction HD1. The upper surface of the second bonding pad 41Ba is arranged on the same plane as the upper surface of the second mold layer 12. The second mold layer 12 surrounds the side surface of the second bonding pad 41Ba.

The process of forming the first metal contact 32Aa and the second metal contact 32Ba may include forming a seed metal layer on the first semiconductor chip 21A, forming a plating resist pattern having openings that provide mold shapes for the first metal contact 32Aa, the second metal contact 32Ba, the first bonding pad 41Aa, and the second bonding pad 41Ba on the seed metal layer, and plating metal into the openings of the plating resist pattern. The first bonding pad 41Aa and the second bonding pad 41Ba may be formed by a plating process in the openings of the plating resist pattern after forming the first metal contact 32Aa and the second metal contact 32Ba. After the first bonding pad 41Aa and the second bonding pad 41Ba are formed, the plating resist pattern is removed, and the seed metal layer that does not overlap with the first bonding pad 41Aa and the second bonding pad 41Ba may be removed.

As illustrated in FIG. 10, the first bonding pad 41Aa may have a structure in which a barrier metal layer 41Aa-1 and a bonding metal layer 41Aa-2 are stacked. The barrier metal layer 41Aa-1 is disposed on the first metal contact 32Aa. The barrier metal layer 41Aa-1 covers the upper surface of the first metal contact 32Aa. The bonding metal layer 41Aa-2 is disposed on the barrier metal layer 41Aa-1. The bonding metal layer 41Aa-2 covers the upper surface of the barrier metal layer 41Aa-1. The barrier metal layer 41Aa-1 may include nickel. The barrier metal layer 41Aa-1 may be a nickel layer. The bonding metal layer 41Aa-2 may include gold. The bonding metal layer 41Aa-2 may be a gold layer. The second bonding pad 41Ba may have the same structure as the first bonding pad 41Aa. The second bonding pad 41Ba may be composed of the same material as the first bonding pad 41Aa.

Referring to FIGS. 11, and 12, the first metal contact to the fourth metal contact 32Ab, 32Bb, 32Cb, and 32Db of the fan-out semiconductor package 300 according to an embodiment of the present disclosure may be composed of bonding wires. As illustrated in FIG. 12, the first metal contact 32Ab includes a bonding section 32Ab-1 bonded to the first chip pad 22A and a vertical section 32Ab-2 connected to the bonding section 32Ab-1. The second metal contact 32Bb, the third metal contact 32Cb, and the fourth metal contacts 32Db each have a structure similar to the first metal contact 32Ab.

The upper ends of the first metal contact 32Ab and the second metal contact 32Bb are arranged on the same plane as the upper surface of the second mold layer 12. A first bonding pad 41Ab is disposed on the first metal contact 32Ab. The first bonding pad 41Ab is disposed on the upper surface of the first metal contact 32Ab and the upper surface of the second mold layer 12 around the first metal contact 32Ab. The first bonding pad 41Ab has a greater planar area than the planar area of the first metal contact 32Ab.

A second bonding pad 41Bb is disposed on the second metal contact 32Bb. The second bonding pad 41Bb is disposed on the upper surface of the second metal contact 32Bb and the upper surface of the second mold layer 12 around the second metal contact 32Bb. The second bonding pad 41Bb has a planar area greater than the planar area of the second metal contact 32Bb.

The upper surfaces of the third metal contact 32Cb and the fourth metal contact 32Db are arranged on the same plane as the upper surface of the third mold layer 13.

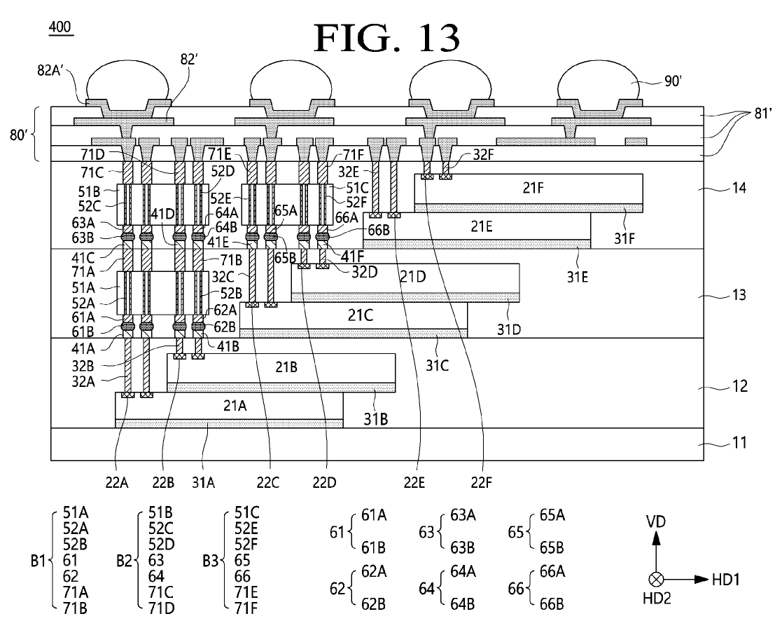

Referring to FIG. 13, a fan-out semiconductor package 400 according to an embodiment of the present disclosure includes a first mold layer 11, a second mold layer 12, a third mold layer 13, a fourth mold layer 14, a first semiconductor chip 21A, a second semiconductor chip 21B, a third semiconductor chip 21C, a fourth semiconductor chip 21D, a fifth semiconductor chip 21E, and a sixth semiconductor chip 21F, a first bonding pad 41A, a second bonding pad 41B, a third bonding pad 41C, a fourth bonding pad 41D, a fifth bonding pad 41E, a sixth bonding pad 41F, a first bridge die B1, a second bridge die B2, a third bridge die B3, and a redistribution layer 80’. The fan-out semiconductor package 400 of FIG. 13, compared to the fan-out semiconductor package 100 of FIG. 1, further includes the fourth mold layer 14, the fifth semiconductor chip 21E, the sixth semiconductor chip 21F, the third bonding pad 41C, the fourth bonding pad 41D, the fifth bonding pad 41E, the sixth bonding pad 41F, the second bridge die B2, and the third bridge die B3.

The third bonding pad 41C is disposed on a first top bump 71A of the first bridge die B1. The fourth bonding pad 41D is disposed on a second top bump 71B of the first bridge die B1. The fifth bonding pad 41E is disposed on a third metal contact 32C. The sixth bonding pad 41F is disposed on a fourth metal contact 32D.

The second bridge die B2 is mounted on the third bonding pad 41C and the fourth bonding pad 41D. The second bridge die B2 includes a second body layer 51B, a third bottom bump 53, a fourth bottom bump 64, a third top bump 71C, a fourth top bump 71D, a third through-electrodes 52C, and a fourth through-electrode 52D.

The second body layer 51B may include silicon. The third bottom bump 63 includes a third metal layer 63A under the second body layer 52B and a third solder layer 63B under the third metal layer 63A. The third solder layer 63B is bonded on the third bonding pad 41C. The fourth bottom bump 64 includes a fourth metal layer 64A under the second body layer 52B and a fourth solder layer 64B under the fourth metal layer 64A. The fourth solder layer 64B is bonded on the fourth bonding pad 41D. The third metal layer 63A and the fourth metal layer 64A may include copper.

The third top bump 71C and the fourth top bump 71D are disposed on the second body layer 52B. The third top bump 71C overlaps with the third bottom bump 63 in the vertical direction VD. The fourth top bump 71D overlaps with the fourth bottom bump 64 in the vertical direction VD. The third top bump 71C and the fourth top bump 71D may include copper.

The third through-electrode 52C extends through or penetrates the second body layer 52B in the vertical direction VD. The lower end of the third through-electrode 52C is connected to the third bottom bump 63, and the upper end of the third through-electrode 52C is connected to the third top bump 71C. The third through-electrode 52C electrically connects the third bottom bump 63 and the third top bump 71C. The width of the third through-electrode 52C in the first horizontal direction HD1 is less than the width of the third bottom bump 63 in the first horizontal direction HD1 and the width of the third top bump 71C in the first horizontal direction HD1. Two third through-electrodes 52C are arranged between the third bottom bump 63 and the third top bump 71C, so that the third bottom bump 63 and the third top bump 71C can be electrically connected. In FIG. 13, the number of third through-electrodes 52C connecting the third bottom bump 63 and the third top bump 71C is two, but other embodiments are not limited thereto. As another example, the number of third through-electrodes connecting the third bottom bump and the third top bump may be one or three or more.

The fourth through-electrode 52D extends through or penetrates the second body layer 52B in the vertical direction VD. The lower end of the fourth through-electrode 52D is connected to the fourth bottom bump 64, and the upper end of the fourth through-electrode 52D is connected to the fourth top bump 71D. The fourth through-electrode 52D electrically connects the fourth bottom bump 64 and the fourth top bump 71D. The width of the fourth through-electrode 52D in the first horizontal direction HD1 is less than the width of the fourth bottom bump 64 in the first horizontal direction HD1 and the width of the fourth top bump 71D in the first horizontal direction HD1. Two fourth through-electrodes 52D are arranged between the fourth bottom bump 64 and the fourth top bump 71D, so that the fourth bottom bump 64 and the fourth top bump 71D can be electrically connected. In FIG. 13, the number of fourth through-electrodes 52D connecting the fourth bottom bump 64 and the fourth top bump 71D is two, but other embodiments are not limited thereto. As another example, the number of fourth through-electrodes connecting the fourth bottom bump and the fourth top bump may be one or three or more.

The third bridge die B3 is mounted on the fifth bonding pad 41E and the sixth bonding pad 41F. The third bridge die B3 includes a third body layer 51C, the fifth bottom bump 65, the sixth bottom bump 66, the fifth top bump 71E, the sixth top bump 71F, and fifth through-electrode 52E, and the sixth through-electrode 52F.

The third body layer 51C may include silicon. The fifth bottom bump 65 includes a fifth metal layer 65A under the third body layer 51C and a fifth solder layer 65B under the fifth metal layer 65A. The fifth solder layer 65B is bonded on the fifth bonding pad 41E. The sixth bottom bump 66 includes a sixth metal layer 66A under the third body layer 51C and a sixth solder layer 66B under the sixth metal layer 66A. The sixth solder layer 68B is bonded on the sixth bonding pad 41F. The fifth metal layer 65A and the sixth metal layer 66A may include copper.

The fifth top bump 71E and the sixth top bump 71F are arranged on the third body layer 51C. The fifth top bump 71E overlaps with the fourth bottom bump 64 in the vertical direction VD. The sixth top bump 71F overlaps with the sixth bottom bump 66 in the vertical direction VD. The fifth top bump 71E and the sixth top bump 71F may contain copper.

The fifth through-electrode 52E extends through or penetrates the third body layer 51C in the vertical direction VD. The lower end of the fifth through-electrode 52E is connected to the fifth bottom bump 65, and the upper end of the fifth through-electrode 52E is connected to the fifth top bump 71E. The fifth through-electrode 52E electrically connects the fifth bottom bump 65 and the fifth top bump 71E. The width of the fifth through-electrode 52E in the first horizontal direction HD1 is less than the width of the fifth bottom bump 65 in the first horizontal direction HD1 and the width of the fifth top bump 71E in the first horizontal direction HD1. Two fifth through-electrodes 52E are arranged between the fifth bottom bump 65 and the fifth top bump 71E to electrically connect the fifth bottom bump 65 and the fifth top bump 71E. In FIG. 13, the number of fifth through-electrodes 52E connecting the fifth bottom bump 65 and the fifth top bump 71E is two, but other embodiments are not limited thereto. As another example, the number of fifth through-electrodes connecting the fifth bottom bump and the fifth top bump may be one or three or more.

The sixth through-electrode 52F extends through or penetrates the third body layer 51C in the vertical direction VD. The lower end of the sixth through-electrode 52F is connected to the sixth bottom bump 66, and the upper end of the sixth through-electrode 52F is connected to the sixth top bump 71F. The sixth through-electrode 52F electrically connects the sixth bottom bump 66 and the sixth top bump 71F. The width of the sixth through-electrode 52F in the first horizontal direction HD1 is less than the width of the sixth bottom bump 66 in the first horizontal direction HD1 and the width of the sixth top bump 71F in the first horizontal direction HD1. Two sixth through-electrodes 52F are arranged between the sixth bottom bump 66 and the sixth top bump 71F to electrically connect the sixth bottom bump 66 and the sixth top bump 71F. In FIG. 13, the number of sixth through-electrodes 52F connecting the sixth bottom bump 66 and the sixth top bump 71F is two, but other embodiments are not limited thereto. As another example, the number of sixth through-electrodes connecting the sixth bottom bump and the sixth top bump may be one or three or more.

The fifth semiconductor chip 21E and the sixth semiconductor chip 21F are stacked on the third mold layer 13. The fifth semiconductor chip 21E is disposed on the third mold layer 13, and the sixth semiconductor chip 21F is disposed on the fifth semiconductor chip 21E. In FIG. 13, two semiconductor chips are stacked on the third mold layer 13, but other embodiments are not limited thereto. One semiconductor chip may be disposed on the third mold layer 13, or three or more semiconductor chips may be stacked.

The fifth semiconductor chip 21E includes a fifth integrated circuit. The fifth integrated circuit may be implemented in various ways depending on the type of the fifth semiconductor chip 21E. In one embodiment, the fifth semiconductor chip 21E may be a memory die, and the fifth integrated circuit may include at least one memory cell.

The fifth semiconductor chip 21E has a fifth chip pad 22E on an upper surface. The fifth chip pad 22E is connected to the fifth integrated circuit. The fifth chip pad 22E is disposed on one of the first horizontal direction HD1 edges of an upper surface of the fifth semiconductor chip 21E, for example, on the left edge. Although only two fifth chip pads 22E are visible in FIG. 13, a plurality of fifth chip pads are disposed in two columns along the second horizontal direction HD2. In another embodiment, the fifth chip pads may be disposed in one column or in three or more columns.

A fifth metal contact 32E is disposed on the fifth chip pad 22E. The fifth metal contact 32E may be a plating metal layer. The plating metal layer may include copper. The fifth metal contact 32E may be a copper pillar.

A fifth adhesive layer 31E is attached to a lower surface of the fifth semiconductor chip 21E, and the fifth semiconductor chip 21E is attached to the third mold layer 13 by the fifth adhesive layer 31E.

The sixth semiconductor chip 21F is offset relative to the fifth semiconductor chip 21E so that the fifth metal contact 32E is exposed. The direction in which the sixth semiconductor chip 21F is offset relative to the fifth semiconductor chip 21E is the same as the direction in which the second semiconductor chip 21B is offset relative to the first semiconductor chip 21A. The sixth semiconductor chip 21F is disposed next to the fifth metal contact 32E and partially overlaps with the fifth semiconductor chip 21E. The fifth metal contact 32E extends substantially in the vertical direction VD while passing next to the sixth semiconductor chip 21F.

The sixth semiconductor chip 21F includes a sixth integrated circuit (not shown). The sixth integrated circuit may be implemented in various ways depending on the type of the sixth semiconductor chip 21F. In one embodiment, the sixth semiconductor chip 21F is a memory die, and the sixth integrated circuit may include at least one memory cell.

The sixth semiconductor chip 21F has a sixth chip pad 22F on an upper surface. The sixth chip pad 22F is connected to the sixth integrated circuit. The sixth chip pad 22F is arranged on one of the first horizontal direction HD1 edges of the upper surface of the sixth semiconductor chip 21A, for example, on the left edge. Although only two sixth chip pads 22F are visible in FIG. 13, a plurality of sixth chip pads are arranged in two columns along the second horizontal direction HD2. As another example, the sixth chip pads may be arranged in one column or in three or more columns.

A sixth metal contact 32F is disposed on the sixth chip pad 22F. The sixth metal contact 32F may be a plating metal layer. The plating metal layer may include copper. The sixth metal contact 32F may be a copper pillar.

Although not illustrated, a base metal layer may be further disposed between the first chip pad 22A and the first metal contact 32A, between the second chip pad 22B and the second metal contact 32B, between the third chip pad 22C and the third metal contact 32C, between the fourth chip pad 22D and the fourth metal contact 32D, between the fifth chip pad 22E and the fifth metal contact 32E, and between the sixth chip pad 22F and the sixth metal contact 32F. The base metal layer electrically connects between the first chip pad 22A and the first metal contact 32A, between the second chip pad 22B and the second metal contact 32B, between the third chip pad 22C and the third metal contact 32C, between the fourth chip pad 22D and the fourth metal contact 32D, between the fifth chip pad 22E and the fifth metal contact 32E, and between the sixth chip pad 22F and the sixth metal contact 32F. The base metal layer limits or suppresses the metal included in the first metal contact to the sixth metal contact 32A, 32B, 32C, 32D, 32E, and 32F from diffusing into the first semiconductor chip to the sixth semiconductor chip 21A, 21B, 21C, 21D, 21E, and 21F. The base metal layer may include nickel. The base metal layer may be a nickel layer.

A sixth adhesive layer 31F is attached to the lower surface of the sixth semiconductor chip 21F, and the sixth semiconductor chip 21F is attached to the fifth semiconductor chip 21E by the sixth adhesive layer 31F.

The fourth mold layer 14 covers the fifth semiconductor chip 21E and the sixth semiconductor chip 21F and surrounds the second bridge die B2, the third bridge die B3, the fifth metal contact 32E, and the sixth metal contact 32F. The fourth mold layer 14 seals the fifth semiconductor chip 21E and the sixth semiconductor chip 21F, the second bridge die B2, the third bridge die B3, the fifth metal contact 32E, and the sixth metal contact 32F. The tops of the fifth metal contact 32E and the sixth metal contact 32F, the tops of the third top bump 71C and the fourth top bump 71D of the second bridge die B2, and the tops of the fifth top bump 71E and the sixth top bump 71F of the third bridge die B3 are exposed to the upper surface of the fourth mold layer 14. The tops of the fifth metal contact 32E and the sixth metal contact 32F, the tops of the third top bump 71C and the fourth top bump 71D, and the tops of the fifth top bump 71E and the sixth top bump 71F are arranged on the same plane as an upper surface of the fourth mold layer 14.

The redistribution layer 80’ is disposed on the fifth metal contact 32E, the sixth metal contact 32F, the second bridge die B2, the third bridge die B3, and the fourth mold layer 14. The redistribution layer 80’ is disposed on tops of the fifth metal contact 32E and the sixth metal contact 32F, the tops of the third top bump 71C and the fourth top bump 71D of the second bridge die B2, the tops of the fifth top bump 71E and the sixth top bump 71F of the third bridge die B3, and the upper surface of the third mold layer 13.

The redistribution layer 80’ includes a dielectric layer 81’ and redistribution patterns 82’. The redistribution pattern 82’ is connected to at least one of the fifth metal contact 32E, the sixth metal contact 32F, the third top bump 71C, the fourth top bump 71D, the fifth top bump 71E, and the sixth top bump 71F.

The first semiconductor chip 21A is connected to the redistribution pattern 82’ through the first metal contact 32A, the first bonding pad 41A, the first bridge die B1, the third bonding pad 41C, and the second bridge die B2. The second semiconductor chip 21B is connected to the redistribution pattern 82’ through the second metal contact 32B, the second bonding pad 41B, the first bridge die B1, the fourth bonding pad 41D, and the second bridge die B2. The third semiconductor chip 21C is connected to the redistribution pattern 82’ through the third metal contact 32C, the fifth bonding pad 41E, and the third bridge die B3. The fourth semiconductor chip 21D is connected to the redistribution pattern 82’ through the fourth metal contact 32D, the sixth bonding pad 41F, and the third bridge die B3. The fifth semiconductor chip 21E is connected to the redistribution pattern 82’ through the fifth metal contact 32E. The sixth semiconductor chip 21F is connected to the redistribution pattern 82’ through the sixth metal contact 32F.

The redistribution patterns 82’ are insulated from each other by the dielectric layer 81’. Some of the redistribution patterns 82’ include a UBM 82A’. An external connection terminal 90’ is connected on the UBM 82A’.

In FIG. 13, the upper surfaces of the first metal contact 32A and the second metal contact 32B are disposed on the same plane as the upper surface of the second mold layer 12, and the first bonding pad 41A and the second bonding pad 41B are disposed on the mold layer 12, but other embodiments are not limited thereto. In another embodiment, the upper surfaces of the first metal contact and the second metal contact may be disposed under the upper surface of the second mold layer, and the upper surfaces of the first bonding pad and the second bonding pad may be disposed on the same plane as the upper surface of the second mold layer.

In FIG. 13, the upper surfaces of the third metal contact 32C and the fourth metal contact 32D may be disposed on the same plane as the upper surface of the third mold layer 13, and the third bonding pad 41C and the fourth bonding pad 41D are disposed on the third mold layer 13, but other embodiments are not limited thereto. In another embodiment, the upper surfaces of the third metal contact and the fourth metal contact may be disposed under the upper surface of the third mold layer, and the upper surfaces of the third bonding pad and the fourth bonding pad may be disposed on the same plane as the upper surface of the third mold layer.

In FIG. 13, the first metal contact to the sixth metal contact 32A, 32B, 32C, 32D, 32E, and 32F are formed of metal layers, but other embodiments are not limited thereto. In another embodiment, the first metal contact to the sixth metal contact may be formed of bonding wires.

Hereinafter, potential effects of the present disclosure are described.

Semiconductor devices having high capacity and wide bandwidth and capable of being driven at low power are sought. To satisfy this need, the number of chip pads of semiconductor chips included in semiconductor devices is increasing and the pitch of the chip pads is decreasing.

Currently, a semiconductor package is being used in which a plurality of semiconductor chips are stacked, metal contacts are formed on the chip pads of the semiconductor chips, a mold layer is formed to seal the semiconductor chips and the metal contacts, and a redistribution layer connected to the metal contacts is formed on the mold layer. The height of the metal contact varies depending on the pitch of the chip pad. As the pitch of the chip pad decreases, the height of the metal contact decreases. To increase the capacity, the number of stacked semiconductor chips needs to be increased. However, as the pitch of the chip pad decreases, the height of the metal contact decreases, so the number of stackable semiconductor chips is limited, which may limit the memory capacity.

According to embodiments of the present disclosure, a bridge die is placed on a metal contact, and the semiconductor chip and the redistribution layer are connected using the metal contact and the bridge die, so the number of stackable semiconductor chips can be increased and the memory capacity can be increased.

While a limited number of detailed embodiments are disclosed in the present disclosure, those skilled in the art will understand that various modifications, additions, and/or substitutions related to these embodiments are possible without departing from the scope and technical concepts of the present disclosure. Therefore, the scope of the present disclosure should not be limited to the disclosed embodiments. All changes within the meaning and range of equivalency of the claims are included within their scope.

What is claimed is:

1. A fan-out semiconductor package comprising:
a first mold layer;
a first semiconductor chip disposed on the first mold layer;
a first metal contact disposed on the first semiconductor chip;
a second mold layer covering the first semiconductor chip and surrounding the first metal contact;
a bonding pad disposed on the first metal contact;
a bridge die mounted on the bonding pad;
a second semiconductor chip disposed on the second mold layer;
a second metal contact disposed on the second semiconductor chip;
a third mold layer covering the second semiconductor chip and surrounding the second metal contact and the bridge die; and
a redistribution layer disposed on the second metal contact, the bridge die, and the third mold layer.

2. The fan-out semiconductor package of claim 1, wherein the bridge die includes:
a body layer;
a bottom bump disposed under the body layer and bonded on the bonding pad;
a top bump disposed on the body layer; and
at least one through-electrode extending through the body layer and electrically connecting the bottom bump and the top bump.

3. The fan-out semiconductor package of claim 2, wherein an upper surface of the top bump is exposed at an upper surface of the third mold layer,
wherein the redistribution layer is disposed on the top bump.

4. The fan-out semiconductor package of claim 2, wherein the bottom bump includes:
a metal layer disposed under the body layer; and
a solder layer disposed under the metal layer and bonded to the bonding pad.

5. The fan-out semiconductor package of claim 4, wherein the metal layer includes copper.

6. The fan-out semiconductor package of claim 2, wherein the top bump includes copper.

7. The fan-out semiconductor package of claim 1, wherein the bonding pad includes:
a barrier metal layer on the first metal contact; and
a bonding metal layer on the barrier metal layer.

8. The fan-out semiconductor package of claim 7, wherein the barrier metal layer includes nickel, and the bonding metal layer includes gold.

9. The fan-out semiconductor package of claim 1, wherein the first metal contact comprises a plating metal layer.

10. The fan-out semiconductor package of claim 1, wherein an upper surface of the first metal contact is on the same plane as an upper surface of the second mold layer.

11. The fan-out semiconductor package of claim 10, wherein a planar area of the bonding pad is greater than a planar area of the first metal contact.

12. The fan-out semiconductor package of claim 1, wherein an upper surface of the bonding pad is on the same plane as an upper surface of the second mold layer.

13. The fan-out semiconductor package of claim 12, wherein a planar area of the bonding pad is equal to a planar area of the first metal contact.

14. The fan-out semiconductor package of claim 1, wherein the first metal contact and the second metal contact each comprise a bonding wire.

15. A fan-out semiconductor package comprising:
a first mold layer;
a first semiconductor chip disposed on the first mold layer;
a first metal contact disposed on the first semiconductor chip;
a second mold layer covering the first semiconductor chip and surrounding the first metal contact;
a first bonding pad disposed on the first metal contact;
a first bridge die mounted on the first bonding pad;
a second semiconductor chip disposed on the second mold layer;
a second metal contact disposed on the second semiconductor chip;
a third mold layer covering the second semiconductor chip and surrounding the second metal contact and the first bridge die;
a second bonding pad disposed on the first bridge die;
a third bonding pad disposed on the second metal contact;
a second bridge die mounted on the second bonding pad;
a third bridge die mounted on the third bonding pad;
a third semiconductor chip mounted on the third mold layer;
a third metal contact disposed on the third semiconductor chip;
a fourth mold layer covering the third semiconductor chip and surrounding the third metal contact, the second bridge die and the third bridge die; and
a redistribution layer disposed on the third metal contact, the second bridge die, the third bridge die, and the fourth mold layer.

16. The fan-out semiconductor package of claim 15, wherein the first bridge die includes:
a body layer;
a bottom bump disposed under the body layer and bonded on the first bonding pad;
a top bump disposed on the body layer; and
at least one through-electrode extending through the body layer and electrically connecting the bottom bump and the top bump.

17. The fan-out semiconductor package of claim 16, wherein the top bump is exposed at an upper surface of the third mold layer,
wherein the second bonding pad is disposed on the top bump.

18. The fan-out semiconductor package of claim 16, wherein the bottom bump includes:
a metal layer disposed under the body layer; and
a solder layer disposed under the metal layer and bonded to the first bonding pad.

19. The fan-out semiconductor package of claim 15, wherein the second bridge die includes:
a body layer;
a bottom bump disposed under the body layer and bonded on the second bonding pad;
a top bump disposed on the body layer; and
at least one through-electrode extending through the body layer and electrically connecting the bottom bump and the top bump.

20. The fan-out semiconductor package of claim 19, wherein the top bump is exposed at an upper surface of the fourth mold layer,
wherein the redistribution layer is disposed on the top bump.
